(19) United States
(12) Patent Application Publication
(10) Pub. No.: US 2025/0175142 A1
(43) Pub. Date: May 29, 2025

(54) ACOUSTIC WAVE DEVICE AND MANUFACTURING METHOD THEREOF

(71) Applicant: RichWave Technology Corp., Taipei City (TW)

(72) Inventors: Ying-Jui Hung, Taipei City (TW); Chin-Lung Yang, Taipei City (TW)

(73) Assignee: RichWave Technology Corp., Taipei City (TW)

(21) Appl. No.: 18/393,739

(22) Filed: Dec. 22, 2023

(30) Foreign Application Priority Data
Nov. 23, 2023 (TW) 112145369

(51) Int. Cl. H03H 9/02; H03H 3/08; H03H 9/145

(52) U.S. Cl. CPC H03H 9/02992; H03H 3/08; H03H 9/1457

(57) ABSTRACT

An acoustic wave device includes a first busbar segment, and two finger electrodes. The first busbar segment is disposed along a first direction. The first finger electrode extends in parallel to a second direction from a first terminal to a second terminal, and the first terminal thereof contacts the first busbar segment. The second finger electrode extends in parallel to the second direction from a first terminal to a second terminal, and the first terminal thereof contacts the first busbar segment. The second finger electrode is disposed to be separated from the first finger electrode. The first busbar segment has a first dimension and a second dimension both measured in parallel to the second direction. The first dimension is located corresponding to the first finger electrode, the second dimension is located corresponding to the second finger electrode, and the first dimension is different from the second dimension.

### TECHNICAL FIELD

The disclosure relates to an acoustic wave device and a manufacturing method thereof, in particular to an acoustic wave device comprising a busbar segment with two different dimensions.

### BACKGROUND

Acoustic wave devices, such as surface acoustic wave (SAW) devices, are used to convert and transmit electrical and acoustic signals. Surface acoustic wave devices have many applications. For example, SAW devices may be used in filters to remove noise and pass wireless signals in a specific frequency band, resulting in a lower transmission loss and/or a stronger resistibility to electromagnetic interference with additional advantages such as a compact size. In addition, SAW devices may also be used as resonators, oscillators, transformers or sensors. For example, acoustic filters may be used in mobile phones. For example, acoustic filters may allow wireless communication to be achieved a narrower frequency band with higher performance. However, according to current technology, SAW devices may suffer from energy leakage due to spurious modes, resulting in a decrease in quality factor. Additionally, reducing the size of acoustic wave devices and/or reducing noise are also challenging.

### SUMMARY

An embodiment of the present disclosure discloses an acoustic wave device. The acoustic wave device may comprise a first busbar segment, a first finger electrode and a second finger electrode. The first busbar segment is disposed along a first direction. The first finger electrode extends in parallel to a second direction from a first terminal to a second terminal, and the first terminal thereof contacts the first busbar segment. The second finger electrode extends in parallel to the second direction from a first terminal to a second terminal, and the first terminal thereof contacts the first busbar segment. The second finger electrode is disposed to be separated from the first finger electrode. The first busbar segment has a first dimension and a second dimension both measured in parallel to the second direction. The first dimension is located corresponding to the first finger electrode, the second dimension is located corresponding to the second finger electrode, and the first dimension is different from the second dimension.

Another embodiment of the present disclosure discloses a method of manufacturing an acoustic wave device. The method may comprise forming a first busbar segment, a first finger electrode and a second finger electrode. The first busbar segment is disposed along a first direction. The first finger electrode extends in parallel to a second direction from a first terminal to a second terminal, and the first terminal of the first finger electrode contacts the first busbar segment. The second finger electrode extends in parallel to the second direction from a first terminal to a second terminal, and the first terminal of the second finger electrode contacts the first busbar segment. The second finger electrode is disposed to be separated from the first finger electrode. The first busbar segment has a first dimension and a second dimension both measured in parallel to the second direction. The first dimension is located corresponding to the first finger electrode. The second dimension is located corresponding to the second finger electrode. The first dimension is different from the second dimension.

### BRIEF DESCRIPTION OF THE DRAWINGS

FIG. 1 is a schematic diagram of an acoustic wave device according to an embodiment of the present disclosure.

FIG. 2 is a partial schematic of an acoustic wave device according to an embodiment of the present disclosure.

FIG. 3 is another partial schematic of an acoustic wave device according to an embodiment of the present disclosure.

FIG. 4A, FIG. 4B, FIG. 5, FIG. 6 and FIG. 7 are schematic diagrams of various acoustic wave devices according to various embodiment of the present disclosure.

FIG. 8 is a flowchart of a method of manufacturing an acoustic wave device according to an embodiment of the present disclosure.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

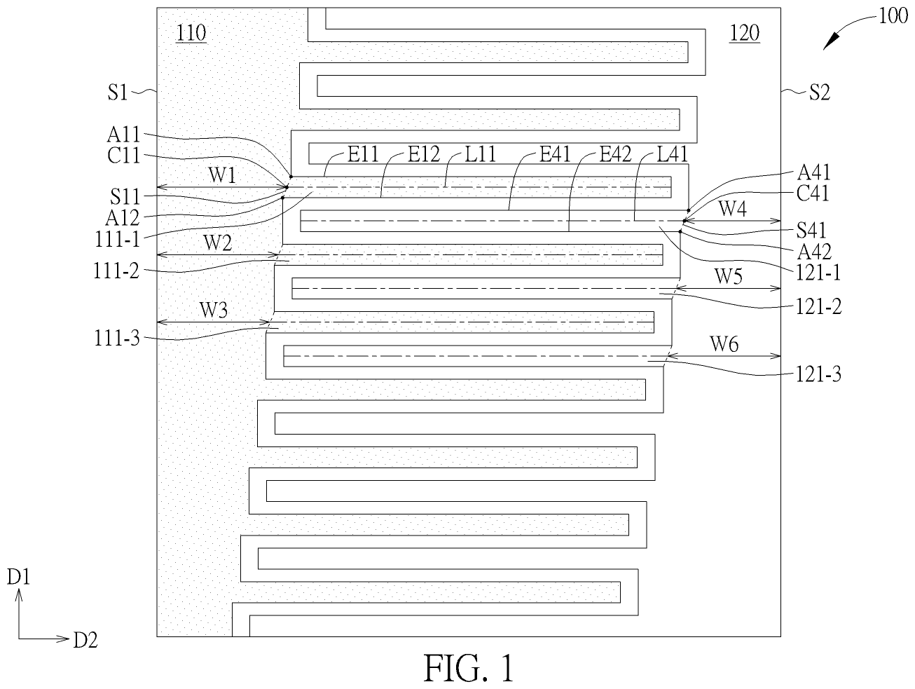

FIG. 1 is a schematic diagram of an acoustic wave device 100 according to an embodiment of the present disclosure. The acoustic wave device 100 may include a first busbar segment 110, a first finger electrode 111-1 and a second finger electrode 111-2. The first busbar segment 110 may be disposed along a first direction D1. The first finger electrode 111-1 may extend in parallel to a second direction D2 from a first terminal to a second terminal, and the first terminal thereof may contact the first busbar segment 110. Similarly, the second finger electrode 111-2 may extend in parallel to the second direction D2 from a first terminal to a second terminal, and the first terminal thereof may contact the first busbar segment 110. As shown in FIG. 1, the second finger electrode 111-2 may be disposed to be separated from the first finger electrode 111-1. Furthermore, the first busbar segment 110 may have a first dimension W1 measured in parallel to the second direction D2 at a position corresponding to the first finger electrode 111-1, and may have a second dimension W2 measured in parallel to the second direction D2 at a position corresponding to the second finger electrode 111-2. For example, the first dimension W1 may be different from the second dimension W2.

In an embodiment, the acoustic wave device 100 may further include a third finger electrode 111-3. The third finger electrode 111-3 may extend in parallel to the second direction D2 from the first terminal to the second terminal, and the first terminal thereof may contact the first busbar segment 110. In other words, the third finger electrode 111-3 may be parallel to the first finger electrode 111-1 and parallel to the second finger electrode 111-2. The third finger electrode 111-3 may be disposed to be separated from the first finger electrode 111-1, and may be further disposed to be separated from the second finger electrode 111-2. Furthermore, the first busbar segment 110 may have a third dimension W3 measured in parallel to the second direction D2 at a position corresponding to the third finger electrode 111-3.

In above embodiments, the acoustic wave device 100 may further include a piezoelectric layer (not shown). The first busbar segment 110, the first finger electrode 111-1, the second finger electrode 111-2, and the third finger electrode 111-3 may be disposed on the piezoelectric layer. For example, various materials used for the piezoelectric layer may include piezoelectric single crystals, piezoelectric crystalline (piezoelectric ceramics), piezoelectric polymers, and piezoelectric composite materials. For example, the material of the piezoelectric layer may include at least one of the followings: zinc oxide (ZnO), aluminum nitride (AlN), lithium tantalate (LiTaO3), lithium niobate (LN), quartz (QZ), Lead titanate (PTO), lead zirconate titanate (PZT) and other materials or combinations thereof. In some embodiments, the piezoelectric layer may be doped with rare earth elements, such as scandium (Sc).

In an embodiment, the first busbar segment 110, the first finger electrode 111-1, the second finger electrode 111-2, and the third finger electrode 111-3 may all include the same conductive material, such as molybdenum (Mo), copper (Cu), aluminum (Al), gold (Au), platinum (Pt), tungsten (W), other suitable metals, and combinations thereof. However, the present disclosure is not such limited. In other embodiments, the first busbar segment 110, the first finger electrode 111-1, the second finger electrode 111-2 and the third finger electrode 111-3 may be substantially made of different conductive materials.

As shown in FIG. 1, the second finger electrode 111-2 may be located between the first finger electrode 111-1 and the third finger electrode 111-3. For example, as for the plurality of finger electrodes extending from the first busbar segment 110, the first finger electrode 111-1 and the third finger electrode 111-3 may be the two finger electrodes most adjacent to the second finger electrode 111-2. In other words, there may be no other finger electrodes extending from the first busbar segment 110 between the first finger electrode 111-1 and the second finger electrode 111-2, and there may be no other finger electrodes extending from the first busbar segment 110 between the second finger electrode 111-2 and the third finger electrode 111-3. However, the above configurations are merely examples and are not intended to limit the present disclosure. In another embodiment, as for the plurality of finger electrodes extending from the first busbar segment 110, the first finger electrode 111-1 or the third finger electrode 111-3 may not be defined as a finger electrode most adjacent to the second finger electrode 111-2. That is, there may be at least one finger electrode extending from the first busbar segment 110 between the first finger electrode 111-1 and the second finger electrode 111-2, or between the second finger electrode 111-2 and the third finger electrode 111-3.

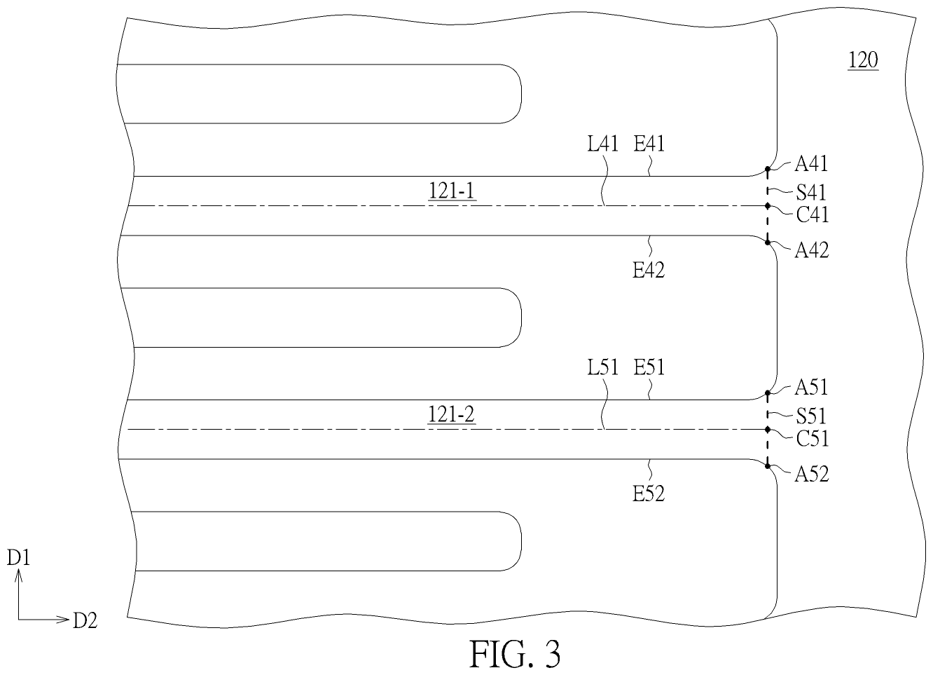

Furthermore, in addition to finger electrodes, other forms of electrodes, such as dummy electrodes, may additionally extend from the first busbar segment 110. As illustrated in FIG. 3 below, in some embodiments, a dummy electrode may be additionally provided between the first finger electrode 111-1 and the second finger electrode 111-2, or between the second finger electrode 111-2 and the third finger electrode 111-3.

As shown in FIG. 1, the first busbar segment 110 may have a first side S1 in parallel to the first direction D1. The first finger electrode 111-1 may have a first centerline L11, a first edge E11 and a second edge E12 all in parallel to the second direction D2. As shown in FIG. 1, a first corner A11 may be formed by the first edge E11 and the first busbar segment 110, a second corner A12 may be formed by the second edge E12 and the first busbar segment 110. A first line S11 (such as, an imaginary straight line) may be drawn between the first corner A11 and the second corner A12, and an intersection point C11 formed by the first line S11 and the first centerline L11 may be defined as the first terminal of the first finger electrode 111-1. In this embodiment, the first dimension W1 is measured in parallel to the second direction D2 from the first side S1 of the first busbar segment 110 to the first terminal (i.e., intersection point C11) of the first finger electrode 111-1. The second dimension W2 and the third dimension W3 may also be defined similarly.

In an embodiment, the third dimension W3 may be equal to or different from the first dimension W1. For example, the first dimension W1 may be greater than the second dimension W2, and the second dimension W2 may be greater than the third dimension W3, that is, W1>W2>W3. In this case, the first dimension W1, the second dimension W2, and the third dimension W3 may be configured as an arithmetic progression sequence or a geometric progression sequence. As for the arithmetic progression sequence, for example, the difference of the first dimension W1 minus the second dimension W2 may be equal to the difference of the second dimension W2 minus the third dimension W3, and it may be expressed as W1−W2=W2−W3. As for the geometric progression sequence, for example, the quotient of the first dimension W1 divided by the second dimension W2 may be equal to the quotient of the second dimension W2 divided by the third dimension W3, and it may be expressed as W1/W2=W2/W3.

However, the present disclosure is not such limited. In other embodiments, the first dimension W1, the second dimension W2, and the third dimension W3 may be configured as a sequence other than the arithmetic progression sequence or the geometric progression sequence. For example, the difference of the first dimension W1 minus the second dimension W2 may be greater than the difference of the second dimension W2 minus the third dimension W3, and it may be expressed as W1−W2>W2−W3. Alternatively, the quotient of the first dimension W1 divided by the second dimension W2 may be smaller than the quotient of the second dimension W2 divided by the third dimension W3, and it may be expressed as W1/W2<W2/W3.

In other embodiments, the first dimension W1 may be greater than the second dimension W2, and the third dimension W3 may be greater than the second dimension W2, that is, W1>W2, and W3>W2. In yet another embodiment, the first dimension W1 is different from the second dimension W2, but the third dimension W3 may be equal to the first dimension W1.

In an embodiment, the acoustic wave device 100 may include a second busbar segment 120, a fourth finger electrode 121-1 and a fifth finger electrode 121-2. The second busbar segment 120 may be disposed along a first direction D1. The fourth finger electrode 121-1 may extend in parallel to the second direction D2 from a first terminal to a second terminal, and the first terminal of the fourth finger electrode may contact with the second busbar segment 120. The fifth finger electrode 121-2 may extend in parallel to the second direction D2 from a first terminal to a second terminal, and the first terminal of the fifth finger electrode 121-2 may contact with the second busbar segment 120. As shown in FIG. 1, the fifth finger electrode 121-2 may be disposed to be separated from the fourth finger electrode 121-1. Furthermore, the second busbar segment 120 may have a fourth dimension W4 measured in parallel to the second direction D2 at a position corresponding to the fourth finger electrode 121-1, and may have a fifth dimension W5 measured in parallel to the second direction D2 at a position corresponding to the fifth finger electrode 121-2.

In an embodiment, the acoustic wave device 100 may further include a sixth finger electrode 121-3. The sixth finger electrode 121-3 may extend in parallel to the second direction D2 from a first terminal to a second terminal, and the first terminal thereof may contact the second busbar segment 120. In other words, the sixth finger electrode 121-3 may be parallel to the fourth finger electrode 121-1 and parallel to the fifth finger electrode 121-2. The sixth finger electrode 121-3 may be disposed to be separated from the fourth finger electrode 121-1 and may further be disposed to be separated from the fifth finger electrode 121-2. Furthermore, the second busbar segment 120 may have a sixth dimension W6 measured in parallel to the second direction D2 at a position corresponding to the sixth finger electrode 121-3. For example, the fifth finger electrode 121-2 may be disposed between the fourth finger electrode 121-1 and the sixth finger electrode 121-3.

FIG. 1 shows a part of the acoustic wave device 100. In the acoustic wave device 100, a plurality of finger electrodes may be configured to form an inter-digital structure. In particular, when viewed along the first direction D1, the first finger electrode 111-1, the fourth finger electrode 121-1, the second finger electrode 111-2, the fifth finger electrode 121-2, the third finger electrode 111-3 and the sixth finger electrode 121-3 may be arranged in an order as listed, and they may be at least partially overlapped with one another along the first direction D1. The first and/or second busbar segments 110 and 120 may also be referred as busbars. In the above embodiments, the first direction D1 may be perpendicular to the second direction D2, but the disclosure is not such limited. In other embodiments, an angle other than 90° may be formed between the first direction D1 and the second direction D2. Furthermore, in the above embodiments, the dimensions W1, W2, and W3 may be widths of the first busbar segment 110 at different positions. Similarly, dimensions W4, W5, W6 may be widths of second busbar segment 120 at different positions.

Furthermore, in the above embodiment, the second busbar segment 120 may have a second side S2 in parallel to the first direction D1. The fourth finger electrode 121-1 may have a fourth centerline L41, a first edge E41 and a second edge E42 all in parallel to the second direction D2. As shown in FIG. 1, a first corner A41 may be formed by the first edge E41 and the second busbar segment 120. A second corner A42 may be formed by the second edge E42 and the second busbar segment 120. A fourth line S41 may be drawn between the first corner A41 and the second corner A42, and the intersection point C41 formed by the fourth line S41 and the fourth centerline L41 may be defined as the first terminal of the fourth finger electrode 121-1. In this embodiment, the fourth dimension W4 is measured in parallel to the second direction D2 from the second side S2 of the second busbar segment 120 to the first terminal (i.e., intersection point C41) of the fourth finger electrode 121-1. The fifth dimension W5 and the sixth dimension W6 may also be defined similarly.

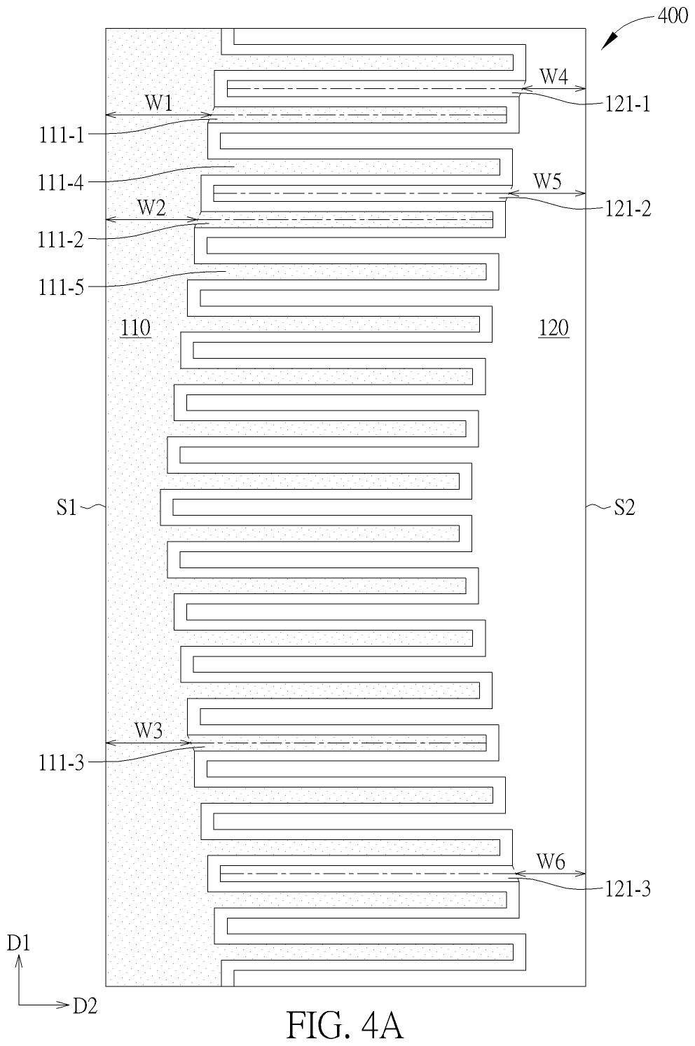

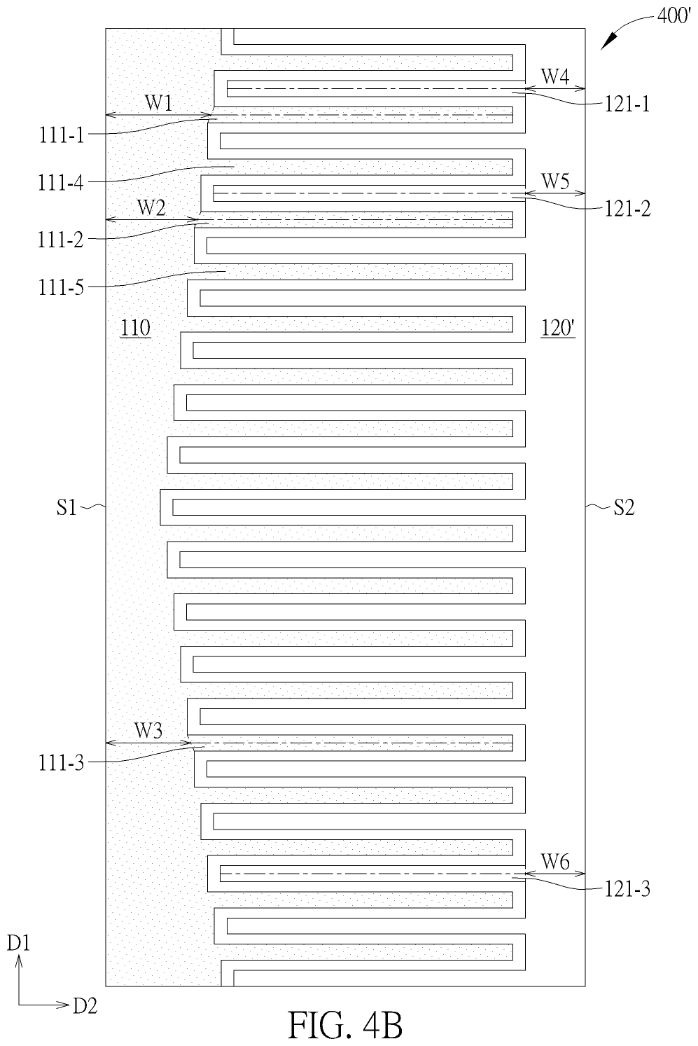

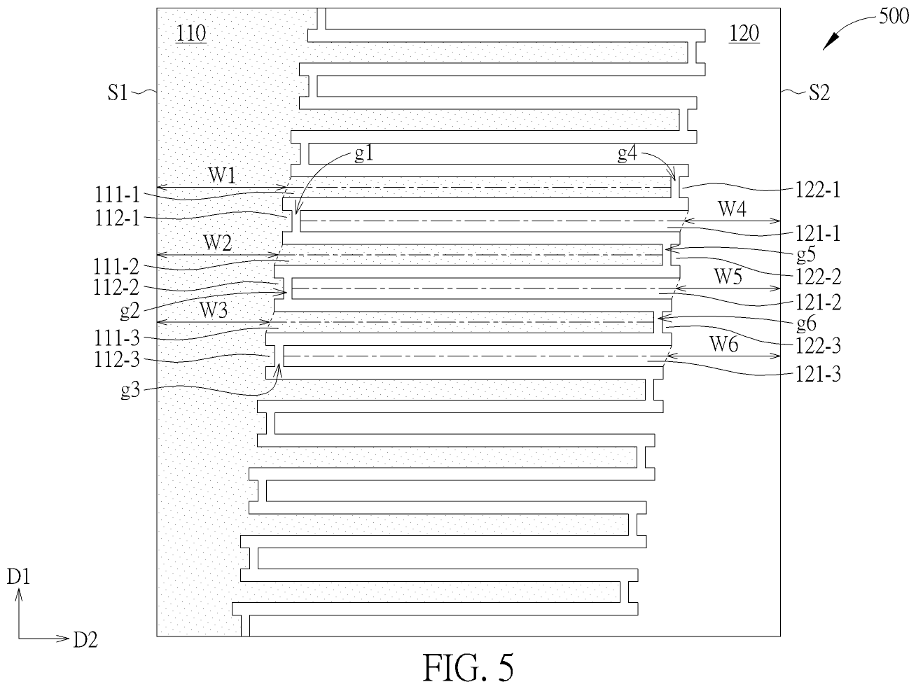

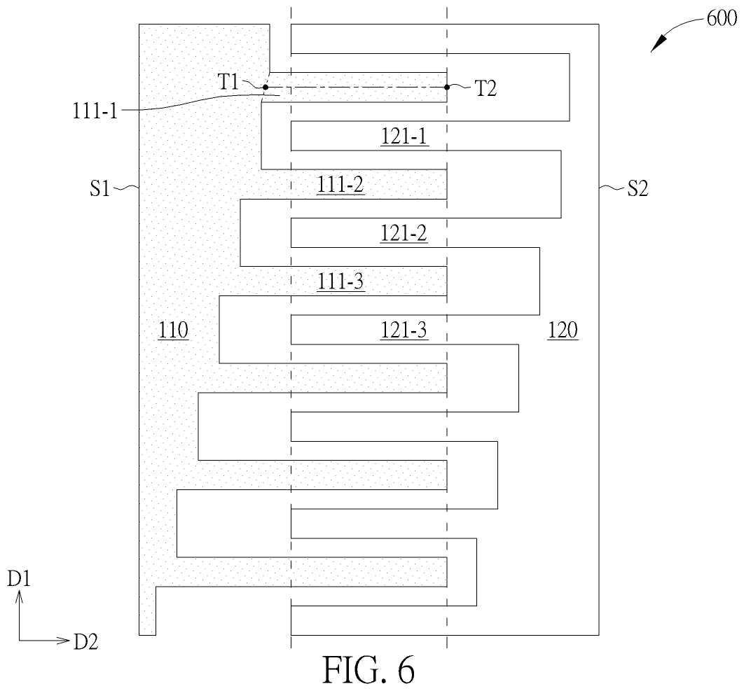

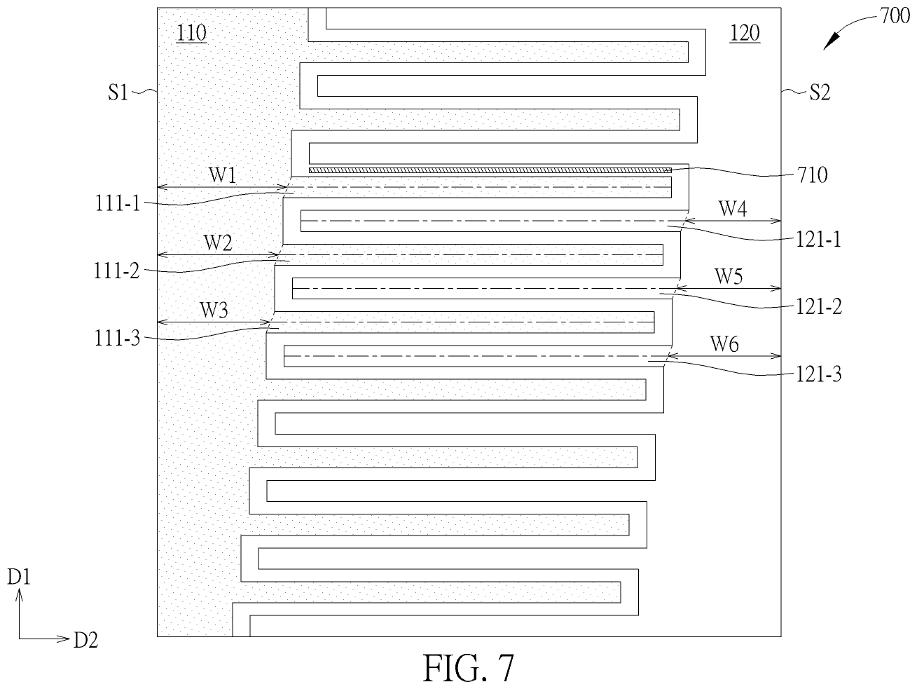

In some embodiments, the fourth dimension W4 may be equal to or different from the fifth dimension W5. In an embodiment where the fourth dimension W4 is equal to the fifth dimension W5, the width of the first busbar segment 110 may be varied, while the width of the second busbar segment 120 may remain unchanged (for example, W1≠W2, and W4=W5), as described below with reference to FIG. 4B.

In an embodiment where the fourth dimension W4 is different from the fifth dimension W5, the width of the first busbar segment 110 may be varied, and the width of the second busbar segment 120 may also be varied. For example, the fourth dimension W4 may be smaller than the fifth dimension W5, and the fifth dimension W5 may be smaller than the sixth dimension W6, which may be expressed as W4<W5<W6. In this case, for example, the fourth dimension W4, the fifth dimension W5, and the sixth dimension W6 may be configured as an arithmetic progression sequence or a geometric progression sequences.

In the embodiment shown in FIG. 1, the corners A11, A12, A41 and A42 are all shown as right angles, but the disclosure is not such limited. In other embodiments, for example, at least one corner between one finger electrode and one busbar segment may be an acute corner, an obtuse corner, or an arc corner, as further described below.

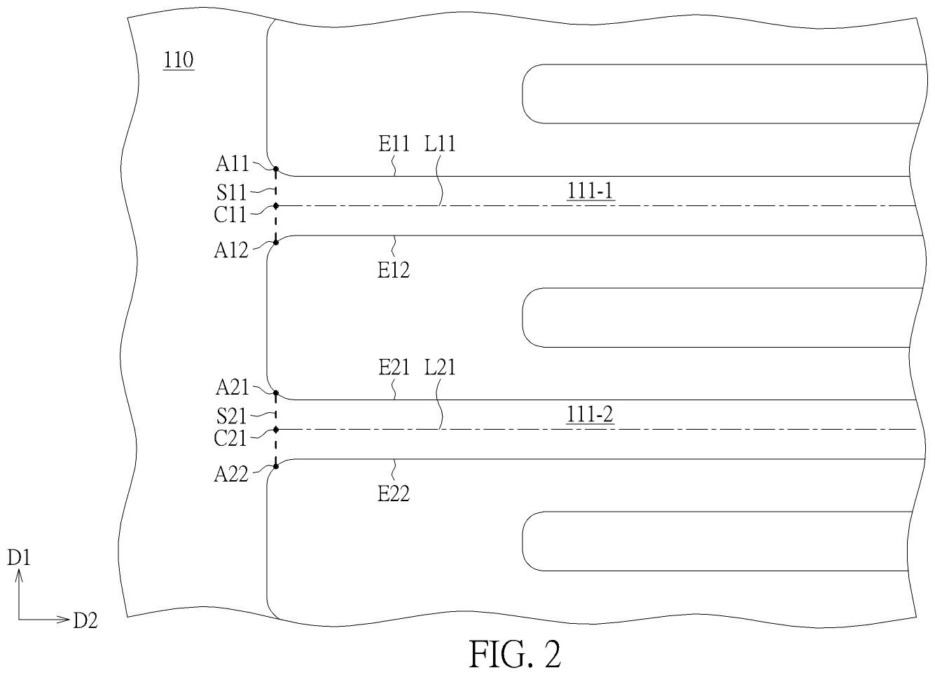

FIG. 2 is a partial schematic of an acoustic wave device according to another embodiment of the present disclosure, and it schematically shows the finger electrodes 111-1, 111-2 and a part of the first busbar segment 110. In FIG. 2, the first finger electrode 111-1 may have a first centerline L11, a first edge E11, and a second edge E12 all parallel to the second direction D2. An arc-shaped first corner may be formed between the first edge E11 and the first busbar segment 110, and the middle position of the arc-shaped first corner is marked as A11. Similarly, an arc-shaped second corner may be formed between the second edge E12 of the first finger electrode 111-1 and the first busbar segment 110, and the middle position of the arc-shaped second corner is marked as A12. A first line S11 may be drawn between the first corner A11 and the second corner A12, and the intersection point C11 formed by the first line S11 and the first centerline L11 may be defined as the first terminal (i.e., located at the intersection point C11).

Similarly, the second finger electrode 111-2 may have a second centerline L21, a first edge E21 and a second edge E22 all in parallel to the second direction D2. The first terminal of the second finger electrode 111-2 may also be defined similarly. As shown in FIG. 2, the first corner A21, the second corner A22, the second line S21 and the intersection point C21 may be similar to the first corner A11, the second corner A12, the first line S11 and the intersection point C11 respectively, and will not be described again here.

FIG. 3 is a partial schematic of an acoustic wave device according to another embodiment of the present disclosure, and it schematically shows the finger electrodes 121-1, 121-2 and a part of the second busbar segment 120. In FIG. 3, the first terminal of the fourth finger electrode 121-1 and the first terminal of the fifth finger electrode 121-2 may be defined at intersection points C41 and C51 respectively. The description may be similar to FIG. 2 above and will not be repeated here.

FIG. 4A, FIG. 4B and FIG. 5 are schematic diagrams of various acoustic wave devices according to various embodiments of the present disclosure.

As shown in FIG. 4A, in the acoustic wave device 400, as for the plurality of finger electrodes extending from the first busbar segment 110, neither the first finger electrode 111-1 nor the third finger electrode 111-3 is a finger electrode most adjacent to the second finger electrode 111-2. As shown in FIG. 4A, the finger electrode 111-4 may be disposed between the first finger electrode 111-1 and the second finger electrode 111-2, and at least one finger electrode 111-5 may be disposed between the second finger electrode 111-2 and the third finger electrode 111-3. In this embodiment, the first dimension W1 may be greater than the second dimension W2, and the third dimension W3 may be greater than the second dimension W2. That is to say, the distance between the first terminal of the first finger electrode 111-1 and the first side S1 of the first busbar segment 110 may be greater than the distance between the first terminal of the second finger electrode 111-2 and the first side S1. The distance between the first terminal of the third finger electrode 111-3 and the first side S1 may be greater than the distance between the first terminal of the second finger electrode 111-2 and the first side S1. Similarly, as for the plurality of finger electrodes extending from the second busbar segment 120, as shown in FIG. 4A, the fourth dimension W4 may be smaller than the fifth dimension W5, and the sixth dimension W6 may be smaller than the fifth dimension W5.

In some embodiments, taking the first busbar segment 110 as an example, a dummy electrode may additionally extend from the first busbar segment 110. In detail, as shown in FIG. 5, the acoustic wave device 500 may additionally include dummy electrodes. For example, the first dummy electrode 112-1 may extend in parallel to the second direction D2 from a first terminal to a second terminal, and the first terminal may contact the first busbar segment 110. The first dummy electrode 112-1 may be disposed between the first finger electrode 111-1 and the second finger electrode 111-2. Furthermore, the first dummy electrode 112-1 may correspond to the fourth finger electrode 121-1, and for example, it may be disposed to be substantially aligned with the fourth finger electrode 121-1 along the second direction D2. Similarly, the second dummy electrode 112-2 may extend in parallel to the second direction D2 from a first terminal to a second terminal, and the first terminal may contact the first busbar segment 110. The second dummy electrode 112-2 may be disposed between the second finger electrode 111-2 and the third finger electrode 111-3, and it may correspond to the fifth finger electrode 121-2. For example, the second dummy electrode 112-2 may be substantially aligned with the fifth finger electrode 121-2 along the second direction D2. The third dummy electrode 112-3 may extend in parallel to the second direction D2 from a first terminal to a second terminal, and the first terminal may contact the first busbar segment 110. The third dummy electrode 112-3 may be disposed to be substantially aligned with the sixth finger electrode 121-3 along the second direction D2.

As shown in FIG. 4B, the acoustic wave device 400′ is similar to the acoustic wave device 400 of FIG. 4A, with the difference being that the width of the second busbar segment 120′ remains unchanged, that is, the fourth dimension W4 may be equal to the fifth dimension W5, and equal to the sixth dimension W6.

In the embodiment shown in FIG. 5, for example, the first dummy electrode 112-1 may be disposed corresponding to the fourth finger electrode 121-1, and a first gap g1 is present between the second terminal of the first dummy electrode 112-1 and the second terminal of the fourth finger electrode 121-1. Similarly, the second terminal of the second dummy electrode 112-2 and the second terminal of the fifth finger electrode 121-2 may be separated by a second gap g2, and/or the second terminal of the third dummy electrode 112-3 and the second terminal of the sixth finger electrode 121-3 may be separated by a third gap g3.

In the above embodiment, the first gap g1, the second gap g2 and the third gap g3 may have the same dimension along the second direction D2, and this is merely for illustration and is not intended to limit the scope of the present disclosure. In other embodiments, the first gap g1, the second gap g2, and the third gap g3 may have different dimensions. Additionally, the first dummy electrode 112-1, the second dummy electrode 112-2, and the third dummy electrode 112-3 may extend the same or different dimensions or distances (for example, lengths) along the second direction D2.

As shown in FIG. 5, the acoustic wave device 500 may further include a fourth dummy electrode 122-1, a fifth dummy electrode 122-2 and a sixth dummy electrode 122-3 all in parallel to the second direction D2. The fourth dummy electrode 122-1, the fifth dummy electrode 122-2 and the sixth dummy electrode 122-3 may extend from the second busbar segment 120 and be configured to respectively correspond to the first finger electrode 111-1, the second finger electrode 111-2, and the third finger electrode 111-3. Furthermore, the fourth gap g4 may be disposed between the fourth dummy electrode 122-1 (for example, the second terminal of the fourth dummy electrode 122-1) and the first finger electrode 111-1 (for example, the second terminal of the first finger electrode 111-1), the fifth gap g5 may be disposed between the fifth dummy electrode 122-2 and the second finger electrode 111-2, and the sixth gap g6 may be disposed between the sixth dummy electrode 122-3 and the third finger electrode 111-3.

In the above embodiment, descriptions about the dummy electrodes 122-1˜122-3 and the gaps g4˜g6 may be referred to these about the dummy electrodes 112-1˜112-3 and the gaps g4˜g6, which will not be repeated here.

Refer to FIG. 4A, FIG. 4B and/or FIG. 5, in these embodiments, the first finger electrode 111-1, the second finger electrode 111-2, and the third finger electrode 111-3 may extend the same dimension or distance along the second direction D2 (for example, a length from the first terminal to the second terminal, respectively). The fourth finger electrode 121-1, the fifth finger electrode 121-2, and the sixth finger electrode 121-3 may extend the same dimension or distance along the second direction D2. However, the present disclosure is not such limited. In other embodiments, for example, at least two of the first finger electrode 111-1, the second finger electrode 111-2, and the third finger electrode 111-3 may have different lengths.

FIG. 6 and FIG. 7 are schematic diagrams of various acoustic wave devices according to various embodiment of the present disclosure.

In the acoustic wave device 600 shown in FIG. 6, taking the first finger electrode 111-1 as an example, the length thereof may be measured from the first terminal T1 to the second terminal T2 along the second direction D2. As shown, the length of the first finger electrode 111-1 may be smaller than the length of the second finger electrode 111-2, and the length of the second finger electrode 111-2 may be smaller than the length of the third finger electrode 111-3. Furthermore, when viewed along the first direction D1, the second terminal E2 of the first finger electrode 111-1, the second terminal of the second finger electrode 111-2, and the second terminal of the third finger electrode 111-3 may be aligned with one another. Similarly, when viewed along the first direction D1, the second terminal of the fourth finger electrode 121-1, the second terminal of the fifth finger electrode 121-2, and the second terminal of the sixth finger electrode 121-3 may be aligned with one another.

The acoustic wave device 700 shown in FIG. 7 may further include a floating electrode 710 extending in parallel to the second direction D2 from the first terminal to the second terminal. As shown, the floating electrode 710 is disposed without contacting the first busbar segment 110 or the second busbar segment 120. The floating electrode 710 may be configured to facilitate reduced spurious modes.

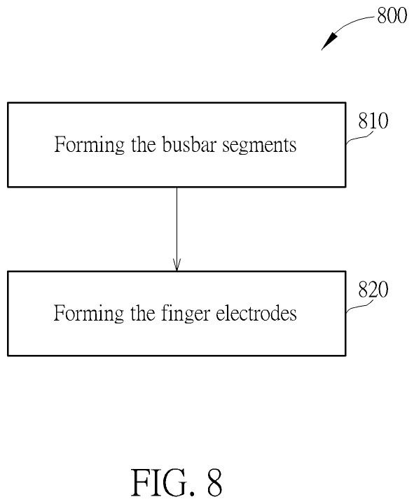

FIG. 8 is a flowchart of a method 800 of manufacturing an acoustic wave device according to an embodiment of the present disclosure. The manufacturing method 800 may include, for example, steps 810 to 820, and the busbar segments are formed in step 810, and finger electrodes are formed in step 820. Steps 810 and 820 may be performed sequentially or simultaneously.

Specifically, in step 810, the first busbar segment 110 and the second busbar segment 120 may be formed. In step 820, the first finger electrode 111-1, the second finger electrode 111-2, the third finger electrode 111-3, the fourth finger electrode 121-1, the fifth finger electrode 121-2 and/or the sixth finger electrode 121-3 may be formed.

At least one acoustic wave device according to embodiments of the present disclosure may include an inter-digital transducer (IDT), and it may be configured to achieve at least one of the following advantages: reduced size of the acoustic wave device, reduced spurious modes, reduced surface acoustic wave noise, etc.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An acoustic wave device comprising:
a first busbar segment disposed along a first direction;
a first finger electrode extending in parallel to a second direction from a first terminal to a second terminal, wherein the first terminal of the first finger electrode contacts the first busbar segment; and
a second finger electrode extending in parallel to the second direction from a first terminal to a second terminal, wherein the first terminal of the second finger electrode contacts the first busbar segment;
wherein the second finger electrode is disposed to be separated from the first finger electrode, and
wherein the first busbar segment has a first dimension and a second dimension both measured in parallel to the second direction, the first dimension is located corresponding to the first finger electrode, the second dimension is located corresponding to the second finger electrode, and the first dimension is different from the second dimension.

2. The acoustic wave device of claim 1, wherein:
the first finger electrode has a first centerline in parallel to the second direction and the first finger electrode further has a first edge and a second edge both in parallel to the first centerline, wherein a first corner is formed by the first edge of the first finger electrode and the first busbar segment, a second corner is formed by the second edge of the first finger electrode and the first busbar segment, and a first line is drawn between the first corner and the second corner, and an intersection point formed by the first line and the first centerline is defined as the first terminal of the first finger electrode;
the second finger electrode has a second centerline in parallel to the second direction, and the second finger electrode further has a first edge and a second edge in parallel to the second centerline, wherein a third corner is formed by the first edge of the second finger electrode and the first busbar segment, a fourth second corner is formed by the second edge of the second finger electrode and the first busbar segment, a second line is drawn between the third corner and the fourth corner, and an intersection point formed by the second line and the second centerline is defined as the first terminal of the second finger electrode; and
the first busbar segment has a first side in parallel to the first direction, the first dimension is measured in parallel to the second direction from the first side of the first busbar segment to the first terminal of the first finger electrode, and the second dimension is measured in parallel to the second direction from the first side of the first busbar segment to the first terminal of the second finger electrode.

3. The acoustic wave device of claim 1, further comprising:
a third finger electrode extending in parallel to the second direction from a first terminal to a second terminal;
wherein the first terminal of the third finger electrode contacts the first busbar segment, and the third finger electrode is disposed to be separated from the first finger electrode;
the second finger electrode is disposed between the first finger electrode and the third finger electrode; and
the first busbar segment further has a third dimension measured in parallel to the second direction, and the third dimension is located corresponding to the third finger electrode.

4. The acoustic wave device of claim 3, wherein the first dimension is greater than the second dimension, and the second dimension is greater than the third dimension.

5. The acoustic wave device of claim 3, wherein the first dimension is greater than the second dimension, and the third dimension is greater than the second dimension.

6. The acoustic wave device of claim 3, wherein:
among finger electrodes extending from the first busbar segment, the first finger electrode and the third finger electrode are two finger electrodes most adjacent to the second finger electrode;
wherein:
a difference of the first dimension minus the second dimension is equal to a difference of the second dimension minus the third dimension; or
a quotient of the first dimension divided by the second dimension is equal to a quotient of the second dimension divided by the third dimension.

7. The acoustic wave device of claim 3, wherein:
among finger electrodes extending from the first busbar segment, the first finger electrode and the third finger electrode are two finger electrodes most adjacent to the second finger electrode;
wherein:
a difference of the first dimension minus the second dimension is different from a difference of the second dimension minus the third dimension; or
a quotient of the first dimension divided by the second dimension is different from a quotient of the second dimension divided by the third dimension.

8. The acoustic wave device of claim 3, further comprising:
a second busbar segment disposed along the first direction;
a fourth finger electrode extending in parallel to the second direction from a first terminal to a second terminal, wherein the first terminal of the fourth finger electrode contacts the second busbar segment; and
a fifth finger electrode extending in parallel to the second direction from a first terminal to a second terminal, wherein the first terminal of the fifth finger electrode contacts the second busbar segment;
wherein the fifth finger electrode is disposed to be separated from the fourth finger electrode, and
wherein the second busbar segment has a fourth dimension and a fifth dimension both measured in parallel to the second direction, the fourth dimension is located corresponding to the fourth finger electrode, the fifth dimension is located corresponding to the fifth finger electrode, and the fourth dimension is different from the fifth dimension.

9. The acoustic wave device of claim 8, wherein:
the fourth finger electrode has a fourth centerline in parallel to the second direction, and the fourth finger electrode further has a first edge and a second edge in parallel to the fourth centerline, wherein a fifth corner is formed by the first edge of the fourth finger electrode and the second busbar segment, a sixth corner is formed by the second edge of the fourth finger electrode and the second busbar segment, a fourth line is drawn between the fifth corner and the sixth corner, and an intersection point formed by the fourth line and the fourth centerline is defined as the first terminal of the fourth finger electrode;
the fifth finger electrode has a fifth centerline in parallel to the second direction, and the fifth finger electrode further has a first edge and a second edge in parallel to the fifth centerline, a seventh corner is formed by the first edge of the fifth finger electrode and the second busbar segment, an eighth corner is formed by the second edge of the fifth finger electrode and the second busbar segment, a fifth line is drawn between the seventh corner and the eighth corner, and an intersection point formed by the fifth line and the fifth centerline is defined as the first terminal of the fifth finger electrode; and
the second busbar segment has a second side in parallel to the first direction, the fourth dimension is measured in parallel to the second direction from the second side of the second busbar segment to the first terminal of the fourth finger electrode, and the fifth dimension is measured in parallel to the second direction from the second side of the second busbar segment to the first terminal of the fifth finger electrode.

10. The acoustic wave device of claim 8, further comprising:
a sixth finger electrode extending in parallel to the second direction from a first terminal to a second terminal;
wherein the first terminal of the sixth finger electrode contacts the second busbar segment, and the sixth finger electrode is disposed to be separated from the fourth finger electrode;
the fifth finger electrode is disposed between the fourth finger electrode and the sixth finger electrode; and
the second busbar segment further has a sixth dimension measured in parallel to the second direction, and the sixth dimension is located corresponding to the sixth finger electrode.

11. The acoustic wave device of claim 10, wherein the fourth dimension is smaller than the fifth dimension, and the fifth dimension is smaller than the sixth dimension.

12. The acoustic wave device of claim 10, wherein the fourth dimension is smaller than the fifth dimension, and the sixth dimension is smaller than the fifth dimension.

13. The acoustic wave device of claim 10, wherein:
along the second direction, a dimension of the first finger electrode, a dimension of the second finger electrode, and a dimension of the third finger electrode are equal to one another; and
along the second direction, a dimension of the fourth finger electrode, a dimension of the fifth finger electrode, and a dimension of the sixth finger electrode are equal to one another.

14. The acoustic wave device of claim 10, wherein:
when viewed along the first direction, the first finger electrode, the fourth finger electrode, the second finger electrode, the fifth finger electrode, the third finger electrode and the sixth finger electrode are arranged in an order as listed, and are arranged to be at least partially overlapped with one another.

15. The acoustic wave device of claim 14, further comprising:
a first dummy electrode extending in parallel to the second direction from a first terminal to a second terminal, wherein the first terminal of the first dummy electrode contacts the first busbar segment, and the first dummy electrode is located corresponding to the fourth finger electrode;
a second dummy electrode extending in parallel to the second direction from a first terminal to a second terminal, wherein the first terminal of the second dummy electrode contacts the first busbar segment, and the second dummy electrode is located corresponding to the fifth finger electrode; and
a third dummy electrode extending in parallel to the second direction from a first terminal to a second terminal, wherein the first terminal of the third dummy electrode contacts the first busbar segment, and the third dummy electrode is located corresponding to the sixth finger electrode;
wherein:
the second terminal of the first dummy electrode and the second terminal of the fourth finger electrode are separated by a first gap;
the second terminal of the second dummy electrode and the second terminal of the fifth finger electrode are separated by a second gap;
the second terminal of the third dummy electrode and the second terminal of the sixth finger electrode are separated by a third gap; and
when measured in parallel to the second direction, the first gap, the second gap and the third gap are equal to one another.

16. The acoustic wave device of claim 14, further comprising:
a fourth dummy electrode extending in parallel to the second direction from a first terminal to a second terminal, wherein the first terminal of the fourth dummy electrode contacts the second busbar segment, and the fourth dummy electrode is located corresponding to the first finger electrode;
a fifth dummy electrode extending in parallel to the second direction from a first terminal to a second terminal, wherein the first terminal of the fifth dummy electrode contacts the second busbar segment, and the fifth dummy electrode is located corresponding to the second finger electrode; and
a sixth dummy electrode extending in parallel to the second direction from a first terminal to a second terminal, wherein the first terminal of the sixth dummy electrode contacts the second busbar segment, and the sixth dummy electrode is located corresponding to the third finger electrode;
wherein:
the second terminal of the fourth dummy electrode and the second terminal of the first finger electrode are separated by a fourth gap;
the second terminal of the fifth dummy electrode and the second terminal of the second finger electrode are separated by a fifth gap;
the second terminal of the sixth dummy electrode and the second terminal of the third finger electrode are separated by a sixth gap; and
when measured in parallel to the second direction, the fourth gap, the fifth gap and the sixth gap are equal to one another.

17. The acoustic wave device of claim 10, wherein:
the second terminal of the first finger electrode, the second terminal of the second finger electrode, and the second terminal of the third finger electrode are aligned with one another along the first direction; and
the second terminal of the fourth finger electrode, the second terminal of the fifth finger electrode, and the second terminal of the sixth finger electrode are aligned with one another along the first direction.

18. The acoustic wave device of claim 8, further comprising:
a floating electrode extending in parallel to the second direction from a first terminal to a second terminal;
wherein the floating electrode is disposed without contacting with the first busbar segment or with the second busbar segment.

19. The acoustic wave device of claim 3, further comprising:
a second busbar segment disposed along the first direction;
a fourth finger electrode extending in parallel to the second direction from a first terminal to a second terminal, wherein the first terminal of the fourth finger electrode contacts the second busbar segment; and
a fifth finger electrode extending in parallel to the second direction from a first terminal to a second terminal, wherein the first terminal of the fifth finger electrode contacts the second busbar segment;
wherein the fifth finger electrode is disposed to be separated from the fourth finger electrode, the second busbar segment has a fourth dimension and a fifth dimension measured in parallel to the second direction, the fourth dimension is located corresponding to the fourth finger electrode, the fifth dimension is located corresponding to the fifth finger electrode, and the fourth dimension is equal to the fifth dimension.

20. A method of manufacturing an acoustic wave device, comprising:
forming a first busbar segment, a first finger electrode and a second finger electrode; wherein:
the first busbar segment is disposed along a first direction;
the first finger electrode extends in parallel to a second direction from a first terminal to a second terminal, wherein the first terminal of the first finger electrode contacts the first busbar segment; and
the second finger electrode extends in parallel to the second direction from a first terminal to a second terminal, wherein the first terminal of the second finger electrode contacts the first busbar segment; and
the second finger electrode is disposed to be separated from the first finger electrode, the first busbar segment has a first dimension and a second dimension both measured in parallel to the second direction, the first dimension is located corresponding to the first finger electrode, the second dimension is located corresponding to the second finger electrode, and the first dimension is different from the second dimension.
